(19) United States
(12) Patent Application Publication
(10) Pub. No.: US 2005/0161810 A1
(43) Pub. Date: Jul. 28, 2005

(54) Semiconductor device

(76) Inventors: Hiroshi Sakura, Osaka (JP); Hisataka Nakabayashi, Osaka (JP); Tetsushi Toyooka, Kyoto (JP); Toru Kusumi, Osaka (JP)

Correspondence Address: MCDERMOTT WILL & EMERY LLP, 600 13TH STREET, N.W., WASHINGTON, DC, 20005-3096, US

(21) Appl. No.: 10/512,829

(22) PCT Filed: Jan. 26, 2004
(86) PCT No.: PCT/JP04/00637

(30) Foreign Application Priority Data
Jan. 27, 2003 (JP) 2003-017112

(51) Int. Cl. H01L 23/48

(52) U.S. Cl. 257/734

(57) ABSTRACT

In a semiconductor device such as a chip having both of an analog circuit and a digital circuit, each of a first power supply wiring (20) for supplying power to an I/O circuit (digital circuit) positioned in the semiconductor device and a third power supply wiring (30) for supplying power to an internal circuit (300) such as an analog circuit formed as a cell, which is a power supply wiring connected to the power supply wiring (20) and positioned in the semiconductor chip (200), is formed from a structure of a multilayer wiring. This lowers the synthesized impedance of these power supply wirings (20, 30) and reduces the influence of power supply noise resulting from the operation of the digital circuit on the analog circuit within the semiconductor chip.

### TECHNICAL FIELD

The present invention relates to a semiconductor device and, more particularly, to a layout pattern for a semiconductor device having both of an analog circuit and a digital circuit.

### BACKGROUND ART

In a semiconductor device having both of an analog circuit and a digital circuit, the operating speed of the digital circuit has been becoming increasingly higher in recent years. In particular, measures should be taken against the influence of the digital circuit on the analog circuit.

As an example of such a semiconductor device, there has been a conventional one disclosed in Japanese Laid-Open Patent Publication No. HEI 7-153915. The semiconductor device has a first power supply wiring for an I/O circuit connected to a lead terminal for power supply via a wire and a second power supply wiring for supplying power to the internal circuit of a semiconductor chip. The semiconductor device operates the second power supply wiring independently of the first power supply wiring by connecting the second power supply wiring to the lead terminal for power supply via a power supply pad and a wire and thereby reduces the influence of power supply noise resulting from the operation of the I/O circuit disposed in the peripheral portion of the semiconductor chip which is exerted on the internal circuit of the semiconductor chip.

### PROBLEM TO BE SOLVED

However, the structure of the conventional semiconductor device has the drawback that a voltage drop occurs due to the first and second power supply wirings each composed of a single-layer wiring, and consequently, the characteristics of the internal circuit of the semiconductor chip, such as an analog circuit, are prone to degradation.

As an example of the semiconductor device, there can also be proposed the one shown in FIG. 7, which will be described herein below. In FIG. 7, 100 is a semiconductor device, 200 is a semiconductor chip included in the semiconductor device 100, 300 is an internal circuit such as an analog circuit provided in the semiconductor chip 200, 11 is the lead terminal of the semiconductor device 100, 20 is a first power supply wiring for supplying power to an I/O circuit (not shown) which is a digital circuit positioned on the outer periphery of the semiconductor chip 200, and 31 and 30 are second and third power supply wirings connected to the first power supply wiring 20. As shown in the enlarged portion of the semiconductor device 100 which is enclosed in the broken rectangle of FIG. 8, the first, second, and third power supply wirings 20, 30, and 31 are connected commonly and the first power supply wiring 20 is connected to the lead terminal 11 for supplying power via the pad 21 and a wire 21a.

As shown in FIG. 9, the first power supply wiring 20 has a double-layered structure and the second power supply wiring 31 is disposed in a layer located thereunder. The respective first power supply wirings 20 in the upper and lower layers are electrically connected through a via 51, while the first power supply wiring 20 in the lower layer and the second power supply wiring 31 are electrically connected through a via 50. In FIG. 9, 80 is a semiconductor substrate and 60 is a well in which the internal circuit of the semiconductor chip 200 is formed.

In the semiconductor device shown in FIGS. 7 to 9, however, power supply noise in the first power supply wiring 20 that has resulted from the operation of the I/O circuit (not shown) positioned on the outer periphery of the semiconductor chip 200 propagates from the first power supply wiring 20 to the second power supply wiring 31 through the via 50 and further to the well 60 on the semiconductor substrate 80 via the wire-to-wire capacitance between the second power supply wiring 31 and the well 60, which disadvantageously influences the analog element composing the internal circuit.

In addition, because the well 60 is formed directly on the semiconductor substrate 80, there is the risk that the noise may propagate from the semiconductor substrate 80 to the well 60 and influence the analog element.

### DISCLOSURE OF THE INVENTION

An object of the present invention is to reduce, in a semiconductor device such as a chip having both of an analog circuit and a digital circuit, the degradation of the operating characteristics of the internal circuit (such as an analog circuit) of the semiconductor chip that has resulted from power supply noise and effectively suppress the propagation of noise from a digital circuit (I/O circuit) or the like to the internal circuit such as the analog circuit.

To attain the foregoing object, the present invention reduces the impedance of a power supply wiring and a ground wiring in a semiconductor device such as a chip having both of an analog circuit and a digital circuit to a value far smaller than a conventional one and thereby effectively suppresses the propagation of the power supply noise to the internal circuit such as the analog circuit, while elongating the propagation path of the power supply noise and thereby effectively reducing the power supply noise.

Specifically, a semiconductor device according to the present invention is characterized in that it comprises: a semiconductor chip; and an internal circuit formed as a cell disposed in the semiconductor chip, the semiconductor device further comprising: a first power supply wiring positioned in the semiconductor chip; a second power supply wiring positioned in the internal circuit and composed of a power supply wiring different from the first power supply wiring and having the same power voltage as the first power supply wiring to supply the power voltage to the internal circuit; and a third power supply wiring connected to the first power supply wiring to supply the power voltage to the internal circuit, wherein the second power supply wiring is connected to a lead terminal for supplying the power voltage by a first pad and a first wire, the first and third power supply wirings are connected to the lead terminal for supplying the power voltage by a second pad and a second wire used commonly by the first and third power supply wirings, and each of the first and third power supply wirings form a multilayer wiring structure such that the first and third power supply wirings are placed in different wiring layers.

The semiconductor device according to the present invention is also characterized in that the multilayer wiring of each of the first and third power supply wirings is formed in a wiring layer higher than a wiring layer in which the second power supply wiring is placed.

The semiconductor device according to the present invention is also characterized in that the internal circuit has a separation layer for providing separation between the semiconductor substrate and a well located thereabove.

The semiconductor device according to the present invention is also characterized in that the internal circuit is an analog circuit and a circuit which receives the power voltage from the first power supply wiring is a digital circuit.

The semiconductor device according to the present invention is also characterized in that the first power supply wiring and the second pad have been formed as a cell.

The semiconductor device according to the present invention is also characterized in that the second power supply wiring and the first pad have been formed as a cell.

The semiconductor device according to the present invention is also characterized in that a distance between the second power supply wiring and the well located above a semiconductor substrate of the semiconductor chip is set shorter than a distance between the second and third power supply wirings.

The semiconductor device according to the present invention is also characterized in that the first, second, and third power supply wirings are first, second, and third ground wirings and the lead terminal for supplying the power voltage is a lead terminal for supplying a ground voltage.

The semiconductor device according to the present invention is also characterized in that the multilayer wiring of each of the first and third power supply wirings is formed in a wiring layer higher than a wiring layer in which the second power supply wiring is placed.

The semiconductor device according to the present invention is also characterized in that the internal circuit has a separation layer for providing separation between the semiconductor substrate and a well located thereabove.

The semiconductor device according to the present invention is also characterized in that the internal circuit is an analog circuit and a circuit which receives the power voltage from the first power supply wiring is a digital circuit.

The semiconductor device according to the present invention is also characterized in that the first power supply wiring and the second pad have been formed as a cell.

The semiconductor device according to the present invention is also characterized in that the second power supply wiring and the first pad have been formed as a cell.

The semiconductor device according to the present invention is also characterized in that a distance between the second power supply wiring and the well located above a semiconductor substrate of the semiconductor chip is set shorter than a distance between the second and third power supply wirings.

Thus, according to the present invention, each of the first and third power supply or ground wirings is formed from a multilayer structure so that the synthesized impedance of the power supply or ground wirings with respect to the internal circuit is reduced. Compared with the conventional structure of a single-layer wiring, therefore, the multilayer structure allows stable power supply to the internal circuit and effectively suppresses the degradation of the characteristics of the internal circuit such as an analog circuit.

In addition, the second power supply or ground wiring has a wiring structure different from that of each of the first and third power supply or ground wirings so that, even when power supply noise resulting from the operation of, e.g., a digital I/O circuit or a clock generating circuit for giving a clock signal to an AD converting circuit each located in a semiconductor chip is propagated to the first and third power supply or ground wirings, the power supply noise is propagated to the lead terminal for supplying the power voltage via the second pad and the second wire and then to the second power supply wiring via the first wire and the first pad. Since the power supply noise is attenuated during the propagation, the influence of the power supply noise on the internal circuit such as the analog circuit is suppressed effectively.

In particular, the present invention forms the first and third power supply or ground wirings in respective layer each higher than the second power supply or ground wiring so that a large capacitance is formed between the second power supply or ground wiring and the internal circuit. This more effectively suppresses the influence of the power supply noise.

Moreover, the semiconductor substrate and the well are separated by the separation layer in the internal circuit according to the present invention so that the propagation of the power supply noise from the semiconductor substrate to the well is also suppressed effectively.

Furthermore, the capacitance between the well and the second power supply (or ground) wiring becomes larger than the capacitance between the second and third power supply (or ground) wirings according to the present invention so that the coupled impedance between the well and the second power supply (or ground) wiring is reduced.

This reduces the amount of noise that has occurred in the first or third power supply (or ground) wiring and propagated to the well.

### BRIEF DESCRIPTION OF THE DRAWINGS

FIG. 1 is an overall structural view showing a semiconductor device according to an embodiment of the present invention;

FIG. 2 is an enlarged view of the principal portion of the semiconductor device;

FIG. 3 is a cross-sectional view of the principal portion of the semiconductor device;

FIG. 4 is a view corresponding to FIG. 2, in which the principal portion of the semiconductor device has been formed as a cell;

FIG. 5 is an enlarged view of the principal portion of another embodiment of the present invention;

FIG. 6 is a view corresponding to FIG. 5, in which the principal portion of the semiconductor device has been formed as a cell;

FIG. 7 is an overall structural view showing a proposed semiconductor device;

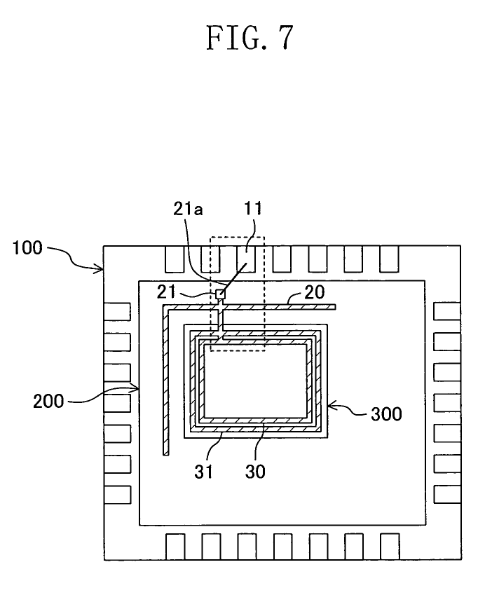

FIG. 8 is an enlarged view showing the principal portion of a proposed semiconductor device; and

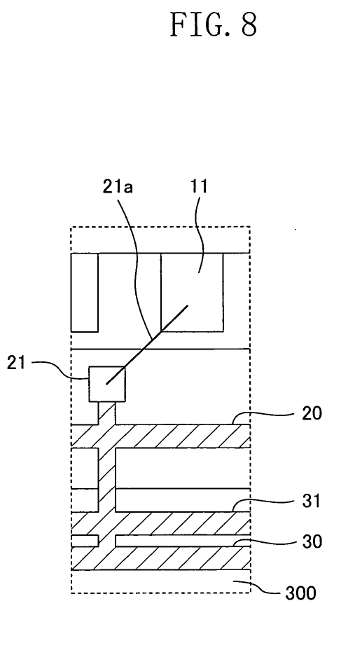

FIG. 9 is a cross-sectional view showing the principal portion of a proposed semiconductor device.

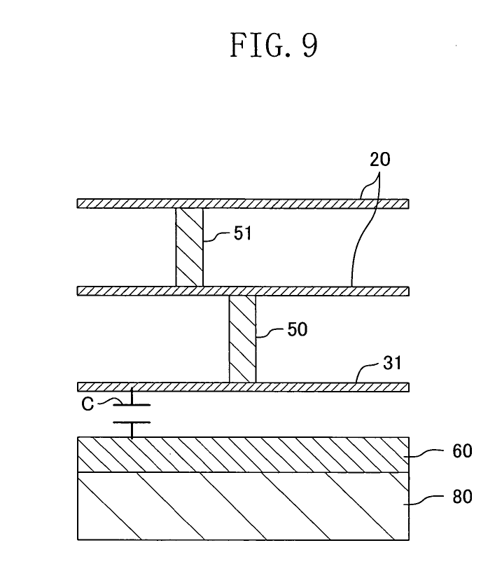

### BEST MODES FOR CARRYING OUT THE INVENTION

Referring to the drawings, the embodiments of the present invention will be described herein below.

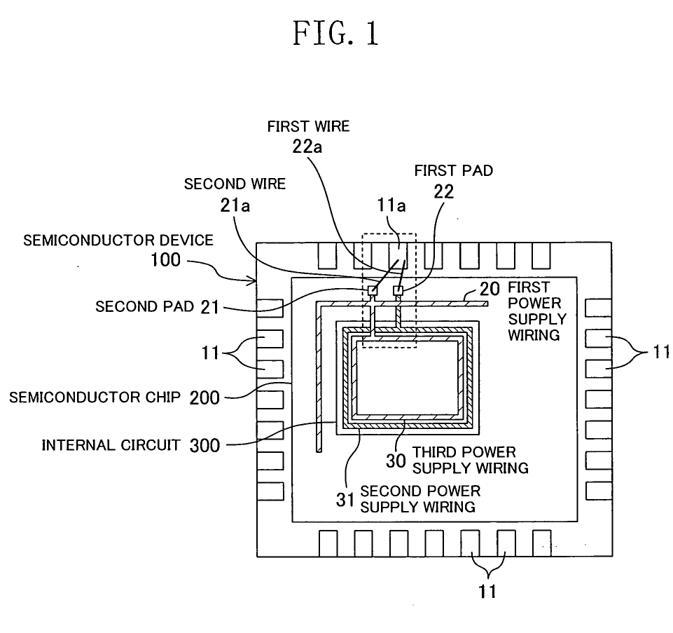

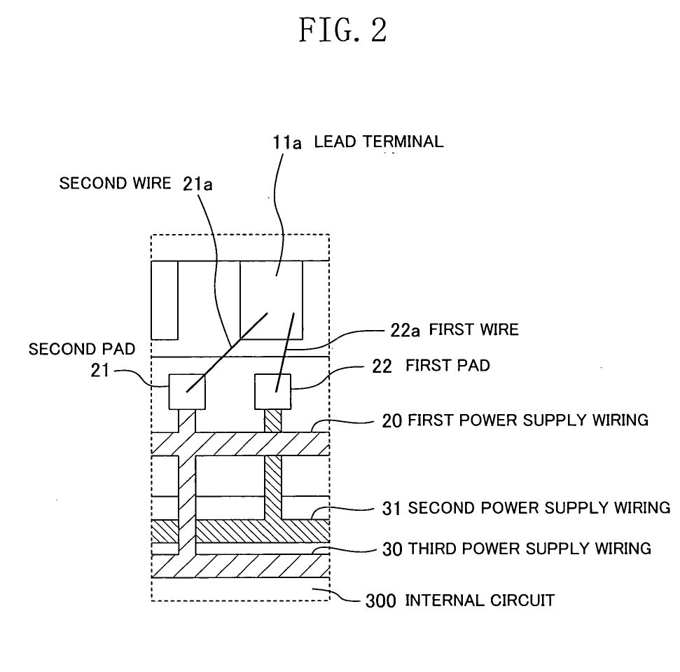

FIG. 1 shows the schematic overall structure of a semiconductor device illustrating an embodiment of the present invention. FIG. 2 is an enlarged view of the portion of the semiconductor device shown in FIG. 1 which is enclosed in the broken rectangle.

In each of FIGS. 1 and 2, 100 is a semiconductor device including a semiconductor chip 200. A large number of external terminals 11 are arranged on the outer periphery of the semiconductor device 100. Of the external terminals 11, external terminals 11a are lead terminals connected to an external power supply.

An analog circuit 300 formed as a cell is disposed as an internal circuit in the semiconductor chip 200. There is also a digital circuit as an I/O circuit disposed on the outer periphery of the semiconductor chip 200, though it is not shown. In the semiconductor chip 200, a first power supply wiring 20 is disposed on the outer periphery thereof and power is supplied to the digital circuit (I/O circuit) via the power supply wiring 20. A second power supply wiring 31 is disposed on the outer periphery of the analog circuit (internal circuit) 300 to suppress power supply noise to the analog circuit 300, while a third power supply wiring 30 is disposed on the inner periphery thereof. Each of the second and third power supply wirings 30 and 31 is for supplying power to the analog circuit 300.

The second power supply wiring 31 is connected to the lead terminals 11a for supplying power via the first pad 22 and the first wire 22a. The third power supply wiring 30 is connected to the first power supply wiring 20 to have the same potential as the first power supply wiring 20 and connected together with the first power supply wiring 20 to the lead terminals 11a for power supply via the common second pad 21 and the common second wire 21a. Although the second power supply wiring 31 is connected to the lead terminals 11a for power supply, it is a power supply wiring different from each of the first and third power supply wirings 20 and 30 connected to the lead terminals 11a.

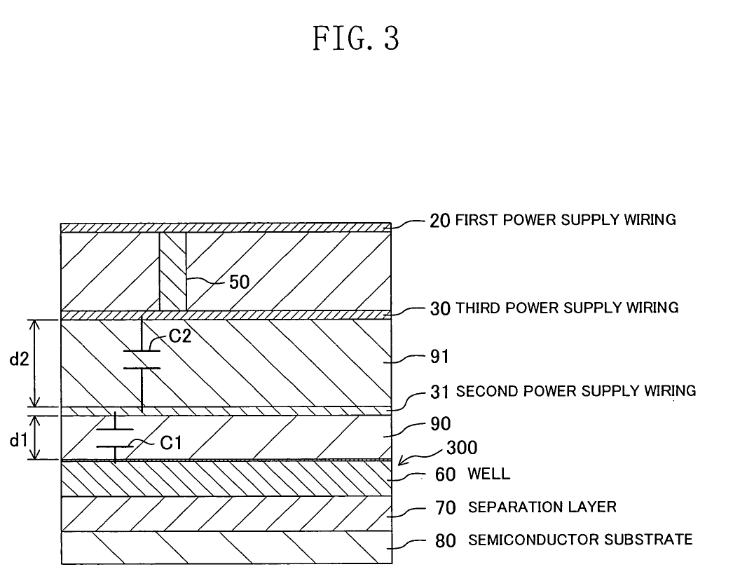

FIG. 3 shows a cross-sectional view of the principal portion of the semiconductor device 100. In the drawing, a separation layer 70 for providing separation between a semiconductor substrate 80 and a well 60 located thereabove and in which the internal circuit 300 is formed is disposed therebetween. The second power supply wiring 31 is disposed above the well 60. The third power supply wiring 30 located on the outer periphery of the analog circuit 300 is disposed in a wiring layer higher than the second power supply wiring 31, while the first power supply wiring 20 is disposed in a wiring layer higher than the third power supply wiring 30. What results is a structure of a multilayer wiring in which the first and third power supply wirings 20 and 30 having the same potential are placed in different wiring layers and connected through the via 50.

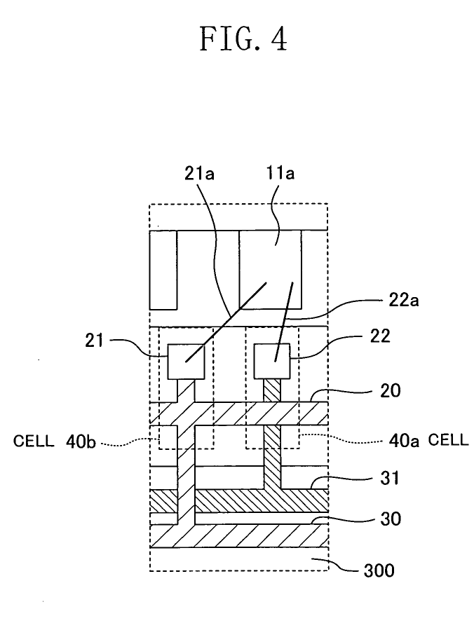

As shown in FIG. 4, the first power supply wiring 20 and the second pad 21 are connected with a smallest permissible distance in terms of layout provided therebetween to compose a cell 40a. Likewise, the second power supply wiring 31 and the first pad 22 are also connected with a smallest permissible distance in terms of layout provided therebetween to compose a cell 40b.

In the semiconductor device according to the present embodiment, each of the first and third power supply wirings 20 and 30 is formed from a structure of a multilayer wiring in which a parallel circuit composed of the power supply wirings 20 and 30 exists between the lead terminals 11a for power supply and the analog circuit 300 within the semiconductor chip 200 to achieve a reduction in the synthesized impedance of the power supply wirings 20 and 30. This allows stable power supply to the analog circuit 300 and effectively suppresses the degradation of the characteristics of the analog circuit 300.

In addition, even when power supply noise that has resulted from the I/O circuit (digital circuit) propagates to the first power supply wiring 20, the power supply noise is initially dissipated to the outside, i.e., to the lead terminals 11a for power supply via the second pad 21 and the second wire 21a and then propagated from the lead terminals 11a for power supply to the second power supply wiring 31 via the first pad 22 and the second wire 22a. Since the power supply noise is greatly attenuated during the propagation, the influence of the power supply noise on the analog circuit 300 is effectively suppressed.

Further, the first power supply wiring 20 for supplying power to the I/O circuit (not shown) positioned on the outer periphery of the semiconductor chip 200 and the third power supply wiring 30 for supplying power to the analog circuit 300 are disposed in respective wiring layers each higher than the second power supply wiring 31. Moreover, the distance d1 between the well 60 and the second power supply wiring 31 is set to be smaller than the distance d2 between the second and third power supply wirings 31 and 30. Furthermore, the relative permeability of an insulating film 90 positioned between the well 60 and the second power supply wiring 31 and the relative permeability of the insulating film 90 positioned between the second and third power supply wirings 31 and 30 are adjusted to have the same value, while the second and third power supply wirings 31 and 30 are designed to have equal widths and follow the same route so that they occupy equal wiring areas. In such a layout, the capacitance C1 between the well 60 and the second power supply wiring 31 is larger than the capacitance C₂ between the second and third power supply wirings 31 and 30 (C1>C2). As a result, the coupled impedance between the well 60 and the second power supply wiring 31 lowers to achieve a reduction in the amount of noise that has occurred in the first or third power supply wiring 20 or 30 and propagated to the well 60 and thereby achieve a further reduction in the influence of the power supply noise.

Additionally, the separation layer 70 has been formed between the semiconductor substrate 80 and the well 60 in which the analog circuit (internal circuit) 300 is formed as shown in FIG. 3 so that noise from the semiconductor substrate 80 to the well 60 is also suppressed effectively.

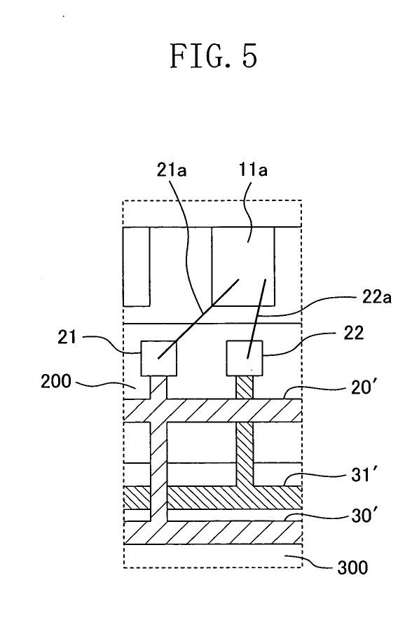

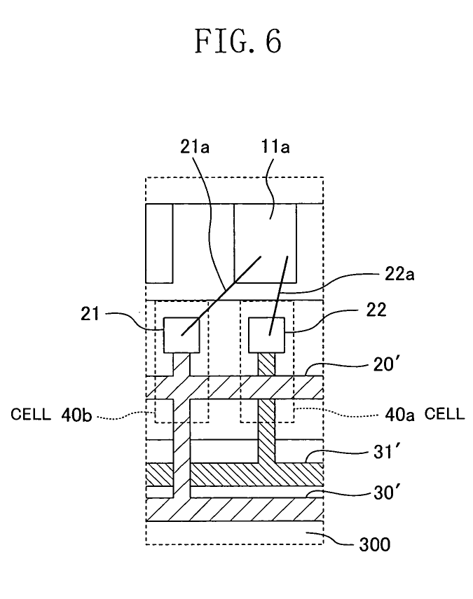

FIGS. 5 and 6 are views illustrating a semiconductor device according to another embodiment of the present invention, which is different from the embodiment already described in that the first power supply wiring 20 has been replaced with a first ground wiring 20′, a second power supply wiring 31 has been replaced with a second ground wiring 31′, and a third power supply wiring 30 has been replaced with a third ground wiring 30′. As for the other structure, it is the same as in the embodiment already described. Accordingly, the same operation and effect as obtained in the embodiment already described are obtainable also in the present embodiment.

Although the I/O circuit (digital circuit) has been disposed on the outer periphery of the semiconductor chip 200 in the foregoing description, it will easily be appreciated that the I/O circuit (digital circuit) may also be disposed on the outer periphery of the internal circuit (analog circuit) 300 such that data in the analog circuit 300 is inputted/outputted to the outside of the semiconductor chip 200 via the I/O circuit (digital circuit). In this case, the first power supply wiring 20 for supplying power to the I/O circuit is also disposed in the internal circuit (analog circuit) 300.

### INDUSTRIAL APPLICABILITY

Since the present invention has thus lowered the impedance of the power supply wirings with respect to the internal circuit of the semiconductor chip, the resulting device is useful as a semiconductor device in which the degradation of the characteristics of the internal circuit due to a voltage drop can be suppressed and the influence of the power supply noise can be suppressed effectively by suppressing the propagation of the power supply noise to the internal circuit.

1. A semiconductor device comprising:
a semiconductor chip; and
an internal circuit formed as a cell disposed in the semiconductor chip, the semiconductor device further comprising:
a first power supply wiring positioned in the semiconductor chip;
a second power supply wiring positioned in the internal circuit and composed of a power supply wiring different from the first power supply wiring and having the same power voltage as the first power supply wiring to supply the power voltage to the internal circuit; and
a third power supply wiring connected to the first power supply wiring to supply the power voltage to the internal circuit, wherein
the second power supply wiring is connected to a lead terminal for supplying the power voltage by a first pad and a first wire,
the first and third power supply wirings are connected to the lead terminal for supplying the power voltage by a second pad and a second wire used commonly by the first and third power supply wirings, and
the first and third power supply wirings form a multilayer wiring structure such that the first and third power supply wirings are placed in different wiring layers.

2. The semiconductor device of claim 1, wherein the multilayer wiring of each of the first and third power supply wirings is formed in a wiring layer higher than a wiring layer in which the second power supply wiring is placed.

3. The semiconductor device of claim 1, wherein the internal circuit has a separation layer for providing separation between the semiconductor substrate and a well located thereabove.

4. The semiconductor device of claim 1, wherein the internal circuit is an analog circuit and a circuit which receives the power voltage from the first power supply wiring is a digital circuit.

5. The semiconductor device of claim 1, wherein the first power supply wiring and the second pad have been formed as a cell.

6. The semiconductor device of claim 1, wherein the second power supply wiring and the first pad have been formed as a cell.

7. The semiconductor device of claim 1, wherein a distance between the second power supply wiring and the well located above a semiconductor substrate of the semiconductor chip is set shorter than a distance between the second and third power supply wirings.

8. The semiconductor device of claim 1, wherein the first, second, and third power supply wirings are first, second, and third ground wirings and the lead terminal for supplying the power voltage is a lead terminal for supplying a ground voltage.

9. The semiconductor device of claim 8, wherein the multilayer wiring of each of the first and third power supply wirings is formed in a wiring layer higher than a wiring layer in which the second power supply wiring is placed.

10. The semiconductor device of claim 8, wherein the internal circuit has a separation layer for providing separation between the semiconductor substrate and a well located thereabove.

11. The semiconductor device of claim 8, wherein the internal circuit is an analog circuit and a circuit which receives the power voltage from the first power supply wiring is a digital circuit.

12. The semiconductor device of claim 8, wherein the first power supply wiring and the second pad have been formed as a cell.

13. The semiconductor device of claim 8, wherein the second power supply wiring and the first pad have been formed as a cell.

14. The semiconductor device of claim 8, wherein a distance between the second power supply wiring and the well located above a semiconductor substrate of the semiconductor chip is set shorter than a distance between the second and third power supply wirings.
